(19) United States
(12) Patent Application Publication
(10) Pub. No.: US 2024/0429358 A1
(43) Pub. Date: Dec. 26, 2024

(54) Electronic Device

(71) Applicant: InnoLux Corporation, Miao-Li County (TW)

(72) Inventors: Shun-Yuan HU, Miao-Li County (TW); Chin-Lung TING, Miao-Li County (TW); Ker-Yih KAO, Miao-Li County (TW); Li-Wei MAO, Miao-Li County (TW); Kung-Chen KUO, Miao-Li County (TW); Yi-Hua HSU, Miao-Li County (TW); Ming-Chun TSENG, Miao-Li County (TW)

(21) Appl. No.: 18/429,571

(22) Filed: Feb. 1, 2024

Related U.S. Application Data
(63) Continuation of application No. 17/105,562, filed on Nov. 26, 2020, now abandoned.
(60) Provisional application No. 62/948,956, filed on Dec. 17, 2019.

(30) Foreign Application Priority Data
Aug. 27, 2020 (CN) 202010878141.9

(51) Int. Cl. H01L 33/62; H01L 25/075; H01L 25/10; H01L 25/13; H01L 25/16

(52) U.S. Cl. CPC H01L 33/62; H01L 25/0753; H01L 25/105; H01L 25/13; H01L 25/167; H01L 2224/16235

(57) ABSTRACT

An electronic device is provided. The electronic device includes a first substrate and a plurality of light-emitting elements disposed on the first substrate. The plurality of light-emitting elements include a contact pad; an intermediate substrate disposed on the contact pad; and a light-emitting unit disposed on the intermediate substrate. The electronic device further includes a second substrate and a first thin-film transistor array disposed on the second substrate for driving at least a portion of the plurality of light-emitting elements. The light-emitting unit is electrically connected to the contact pad through a via hole that penetrates the intermediate substrate.

### CROSS REFERENCE TO RELATED APPLICATIONS

This application is a Continuation of U.S. patent application Ser. No. 17/105,562, filed on Nov. 26, 2020, which claims the benefit of U.S. Provisional Application No. U.S. 62/948,956, filed on Dec. 17, 2019, and claims priority of China Patent Application No. 202010878141.9, filed on Aug. 27, 2020, the entirety of which are incorporated by reference herein.

### BACKGROUND

### Technical Field

The present disclosure relates to an electronic device, and in particular it relates to an electronic device in which a light-emitting element and a thin-film transistor array are disposed on different substrates.

### Description of the Related Art

Electronic products equipped with display panels, such as smartphones, tablet computers, notebook computers, displays, and televisions, have become indispensable necessities in modern society. With the flourishing development of these portable electronic products, consumers have high expectations regarding their quality, functionality, or price.

In general, a light-emitting element and a driving element (such as a thin-film transistor array) are disposed on the same substrate. The light-emitting unit may be directly disposed on the thin-film transistor driving substrate. Therefore, in selecting what materials and manufacturing processes to use for a thin-film transistor driving substrate, compatibility with the manufacturing process of the light-emitting element (such as the process of bonding the light-emitting element and the substrate) needs to be taken into account. However, this may lead to lower process yield or a higher cost. For example, a material that is suitable for a thin-film transistor driving substrate may not be suitable for bonding, fixing, or forming via holes.

In view of the foregoing, although existing electronic devices (including the light-emitting element and the driving element) are substantially adequate for their intended purposes, they are not satisfactory in all respects. Therefore, the development of structural designs that can improve the quality or reliability of such electronic devices is still one of the current research topics in the industry.

### SUMMARY

In accordance with some embodiments of the present disclosure, an electronic device is provided. The electronic device includes a first substrate and a plurality of light-emitting elements disposed on the first substrate. The plurality of light-emitting elements include a contact pad; an intermediate substrate disposed on the contact pad; and a light-emitting unit disposed on the intermediate substrate. The electronic device further includes a second substrate and a first thin-film transistor array disposed on the second substrate for driving at least a portion of the plurality of light-emitting elements. The light-emitting unit is electrically connected to the contact pad through a via hole that penetrates the intermediate substrate.

In accordance with some embodiments of the present disclosure, an electronic device is provided. The electronic device includes a plurality of light-emitting elements and a first thin-film transistor array. The first thin-film transistor array is used to drive at least a portion of the plurality of light-emitting elements, and the plurality of light-emitting elements and the first thin-film transistor array are disposed on different substrates.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a partial cross-sectional diagram of an electronic device in accordance with some embodiments of the present disclosure;

FIG. 2 is a unit circuit diagram of an electronic device in accordance with some embodiments of the present disclosure;

FIG. 3 is a structural enlarged diagram of region A in FIG. 1 in accordance with some embodiments of the present disclosure;

FIG. 4 is a bottom-view diagram of an electronic device in accordance with some embodiments of the present disclosure;

FIG. 5 is a bottom-view diagram of an electronic device in accordance with some embodiments of the present disclosure;

FIG. 6 is a partial cross-sectional diagram of an electronic device in accordance with some embodiments of the present disclosure;

FIG. 7 is a partial cross-sectional diagram of an electronic device in accordance with some embodiments of the present disclosure;

FIG. 8 is a partial cross-sectional diagram of an electronic device in accordance with some embodiments of the present disclosure;

FIG. 9 is a partial cross-sectional diagram of an electronic device in accordance with some embodiments of the present disclosure;

FIG. 10 is a partial cross-sectional diagram of an electronic device in accordance with some embodiments of the present disclosure;

FIG. 11 is a top-view diagram of an electronic device in accordance with some embodiments of the present disclosure;

FIG. 12 is a partial cross-sectional diagram of an electronic device in accordance with some embodiments of the present disclosure;

FIG. 13 is a partial cross-sectional diagram of an electronic device in accordance with some embodiments of the present disclosure;

FIG. 14 is a partial cross-sectional diagram of an electronic device in accordance with some embodiments of the present disclosure.

### DETAILED DESCRIPTION

The electronic device of the present disclosure is described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. The embodiments are used merely for the purpose of illustration. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments.

The present disclosure can be understood by referring to the following detailed description in connection with the accompanying drawings. It should be noted that, in order to allow the reader to easily understand the drawings, several drawings in the present disclosure only depict a portion of the electronic device, and the specific elements in the drawings are not drawn to scale. In addition, the number and size of each element in the drawings are only for illustration, and are not limited the scope of the present disclosure.

Throughout the present disclosure and the appended claims, certain terms are used to refer to specific elements. Those skilled in the art should understand that electronic device manufacturers may refer to the same element with different names. The present disclosure does not intend to distinguish between elements that have the same function but different names. In the specification and claims, the terms “comprising”, “including”, “having” and the like are open-ended phrases, so they should be interpreted as “including but is not limited to . . . ”. Therefore, when the terms “comprising”, “including” and/or “having” are used in the description of the present disclosure, they specify the corresponding features, regions, steps, operations and/or components, but do not exclude the existence of one or more corresponding features, regions, steps, operations and/or components.

Directional terms mentioned in the present disclosure, such as “upper”, “lower”, “front”, “rear”, “left”, “right”, etc., are only the directions referring to the drawings. Therefore, the directional terms are used for illustration, and the present disclosure is not limited thereto. In the drawings, each drawing depicts general features of methods, structures, and/or materials used in particular embodiments. However, these drawings should not be interpreted as defining or limiting the scope or property encompassed by these embodiments. For example, for clarity, the relative sizes, thicknesses, and positions of the various layers, regions, and/or structures may be reduced or enlarged.

When a corresponding component (such as a layer or region) is referred to as “(disposed or located) on another component”, it may be directly (disposed or located) on another component, or there may be other components between them. On the other hand, when a component is referred to as “directly (disposed or located) on another component”, there is no component existing between them. In addition, when a component is referred to as “(disposed or located) on another component”, the two have an upper-lower relationship in a top-view direction, and this component may be above or below another component, and the upper-lower relationship depends on the orientation of the device.

In addition, the term “connected” described in the specification and claims may not only mean direct connection between one element with another element, but also indirect connection and electrical connection between one element with another element.

The terms “about”, “equal to”, “the same as”, “identical to”, “substantially” or “approximately” are generally interpreted as being within 20% of a given value or range, or within 10%, 5%, 3%, 2%, 1% or 0.5% of the given value or range.

The ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is used to make a component with a certain name can be clearly distinguished from another component with the same name. The same words may not be used in the claims and the specification. Accordingly, the first component in the specification may be the second component in the claims.

It should be noted that the following embodiments can replace, recombine, and mix features in several different embodiments to complete other embodiments without departing from the spirit of the present disclosure. The features between the various embodiments can be combined and used arbitrarily as long as they do not violate or conflict the spirit of the present disclosure.

In the present disclosure, the length and the width of the component can be measured from an optical microscope image, and the thickness of the component can be measured from a cross-sectional image in an electron microscope, but it is not limited thereto. In addition, certain errors may exist between any two values or directions used for comparison. If the first value is equal to the second value, it implies that there may be an 10% error between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiments of the present disclosure, an electronic device is provided, and the electronic device includes a light-emitting element and a thin-film transistor array disposed on different substrates. In this way, the selection of the substrate material and manufacturing process of the thin-film transistor array and the light-emitting element can be independent from each other. Therefore, the process yield, or the product reliability can be improved, or the costs can be reduced. In addition, in accordance with some embodiments, the size of the substrate on which the thin-film transistor array is disposed is smaller than the size of the substrate on which the light-emitting element is disposed, thereby increasing the space available for electrical connection between the thin-film transistor array and the light-emitting element (for example, increasing the connection space or increasing the number of contacts).

In accordance with some embodiments of the present disclosure, the electronic device may include a display device, a light-emitting device, a touch device, a sensing device, an antenna device, or a tiled device (a tiled device with any of the above functions or combined functions), but it is not limited thereto. The electronic device may include a bendable electronic device or a flexible electronic device, but it is not limited thereto. The electronic device may include, for example, liquid-crystal, light-emitting diode (LED), quantum dot (QD), fluorescence, phosphor, other suitable materials, or a combination thereof. The light-emitting diode may include, for example, an organic light-emitting diode (OLED), a miniature light-emitting diode (micro-LED, mini-LED), or a quantum dot light-emitting diode (QLED, QDLED), but it is not limited thereto. In accordance with some embodiments, the electronic device may include a panel and/or a backlight module. The panel may include, for example, a liquid-crystal panel, but it is not limited thereto. It should be understood that a display device will be used as an example to describe the electronic device of the present disclosure, but the present disclosure is not limited thereto.

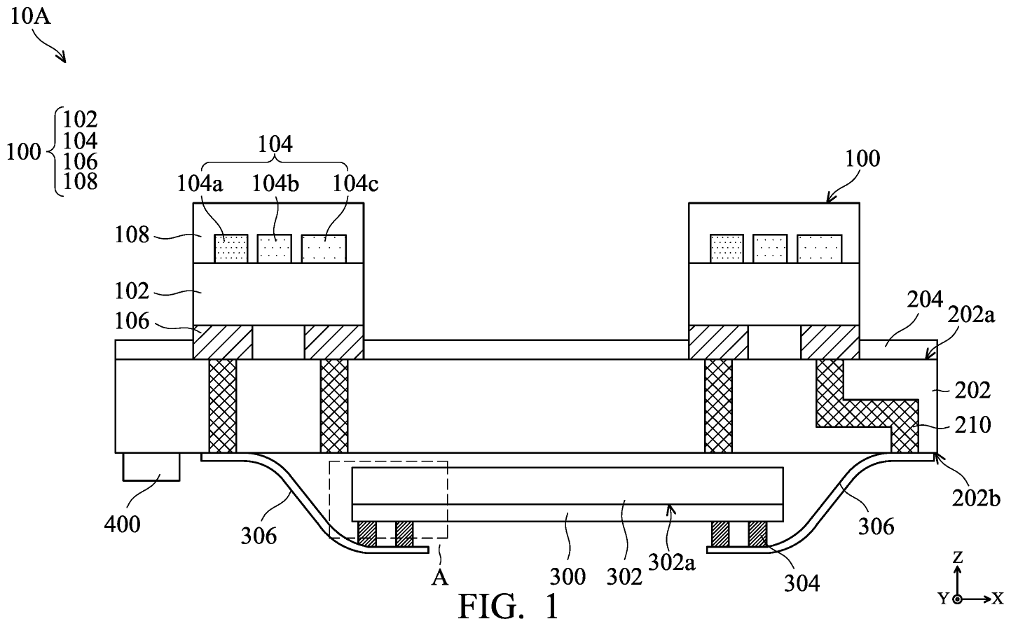

Refer to FIG. 1, which is a partial cross-sectional diagram of an electronic device 10A in accordance with some embodiments of the present disclosure. It should be understood that, for clarity of description, some elements in the electronic device 10A may be omitted, and only schematically illustrates some elements formed or disposed on a first substrate 202 or a second substrate 302, e.g., a part of the light-emitting elements 100 and a part of the thin-film transistor arrays 300. In accordance with some embodiments, additional features or elements can be optionally added to the electronic device 10A. In accordance with some embodiments, some of the features of the electronic device 10 described below may be optionally replaced or omitted.

As shown in FIG. 1, in accordance with some embodiments, the electronic device 10A may include a thin-film transistor array 300 and a plurality of light-emitting elements 100, and the thin-film transistor array 300 may be used to drive at least a portion of the light-emitting elements 100. For example, in accordance with some embodiments, the electronic device 10A may include a plurality of thin-film transistor arrays 300, and the thin-film transistor arrays 300 may be used to drive different portions of the light-emitting elements 100 or the light-emitting elements 100 at different regions. Furthermore, as shown in FIG. 1, the light-emitting elements 100 and the thin-film transistor array 300 are disposed on different substrates. Specifically, in accordance with some embodiments, the electronic device 10A may include a first substrate 202 and a second substrate 302. The light-emitting elements 100 may be disposed on the first substrate 202 and the thin-film transistor array 300 may be disposed on the second substrate 302.

In accordance with some embodiments, the light-emitting elements 100 and the second substrate 302 are disposed on different sides of the first substrate 202. Specifically, the first substrate 202 has a first surface 202a and a second surface 202b located on opposite sides. In accordance with some embodiments, the light-emitting elements 100 are disposed on the first surface 202a, and the second substrate 302 is disposed on the second surface 202b. The light-emitting elements 100 and the second substrate 302 may be in contact with the first substrate 202 or not in direct contact with the first substrate 202. As shown in FIG. 1, in accordance with some embodiments, the light-emitting elements 100 are in contact with the first substrate 202, but the second substrate 302 is not in contact with the first substrate 202.

Furthermore, the first substrate 202 may include a rigid substrate or a flexible substrate. In accordance with some embodiments, the first substrate 202 may be a printed circuit board (PCB). In accordance with some embodiments, the material of the first substrate 202 may include ceramic, aluminum, copper, glass fiber, other suitable materials, or a combination thereto, but it is not limited thereto. In accordance with some embodiments, the first substrate 202 may include a metal-glass fiber composite plate, or a metal-ceramic composite plate, but it is not limited thereto.

In accordance with some embodiments, the light-emitting elements 100 may include, but are not limited to, inorganic light-emitting diodes, micro-LEDs, mini-LEDs, organic light-emitting diodes, (OLED), or quantum dot light-emitting diodes (QLED, QDLED). In accordance with some embodiments, the light-emitting elements 100 may be arranged in an array. In accordance with some embodiments, the light-emitting elements 100 may include a light-emitting diode package, a light-emitting diode chip, or a combination of thereof. In other words, the light-emitting elements 100 may exist in a packaged form or a bare die form. In accordance with some embodiments, the packaging of the light-emitting elements 100 may include surface-mount devices (SMD) packaging of light-emitting diodes, chip-on-board (COB) packaging of light-emitting diodes, the packaging of miniature light-emitting diodes or flip-chip light-emitting diodes, the packaging of organic light-emitting diodes, other suitable packaging form, or a combination thereof, but it is not limited thereto. FIG. 1 illustrates an example in which the light-emitting elements 100 are light-emitting diode packages. In detail, in accordance with some embodiments, the light-emitting element 100 may include an intermediate substrate 102, a light-emitting unit 104, a contact pad 106 and a protective layer 108.

In accordance with some embodiments, the intermediate substrate 102 may be disposed between the light-emitting unit 104 and the contact pad 106, and the light-emitting unit 104 may be electrically connected to the contact pad 106 through a via hole (not illustrated) that penetrates the intermediate substrate 102, but it is not limited thereto. In accordance with some embodiments, the material of the intermediate substrate 102 may include glass, ceramic, plastic, other suitable materials, or a combination thereof, but it is not limited thereto. In accordance with some embodiments, the material of the intermediate substrate 102 may include epoxy resins, polymerized siloxanes (silicone), polyimide (PI), polyethylene terephthalate (PET), polycarbonate (PC), other suitable materials, or a combination thereof, but it is not limited thereto. In addition, in accordance with some embodiments, the intermediate substrate 102 may include a metal-glass fiber composite plate, or a metal-ceramic composite plate, but it is not limited thereto.

In accordance with some embodiments, the light-emitting element 100 may include a plurality of light-emitting units 104, and the light-emitting units 104 may serve as light sources of an electronic device. In accordance with some embodiments, a light-emitting subunit 104a, a light-emitting subunit 104b, and a light-emitting subunit 104c may emit light of a single color, or the light-emitting subunit 104a, the light-emitting subunit 104b and the light-emitting subunit 104c may emit light of different colors. In accordance with some embodiments, the light-emitting unit 104 may combine or mix the light of different colors emitted from the light-emitting subunit 104a, the light-emitting subunit 104b, and the light-emitting subunit 104c to emit light (for example, to produce white light). In accordance with some embodiments, the light-emitting unit 104 may emit light of a single color as the light source of the device. In accordance with some embodiments, the light-emitting element 100 may correspond to one pixel, and the light-emitting element 100 may have a suitable number of light-emitting units 104 (e.g., the light-emitting subunit 104a, the light-emitting subunit 104b, and the light-emitting subunit 104c). In accordance with some embodiments, the light-emitting subunit 104a, the light-emitting subunit 104b, and the light-emitting subunit 104c may be three light-emitting diode dies corresponding to three sub-pixels. For example, in accordance with some embodiments, the light-emitting subunit 104a, the light-emitting subunit 104b, and the light-emitting subunit 104c may be red, green, and blue sub-pixels arranged in a suitable manner, but the present disclosure is not limited thereto. In accordance with some other embodiments, one light-emitting element 100 may include red, green, blue, or white light-emitting units (sub-pixels), or light-emitting units of other suitable colors, but the present disclosure is not limited thereto. In addition, in accordance with some embodiments, the light-emitting subunit 104a, the light-emitting subunit 104b, and the light-emitting subunit 104c may be light-emitting diode dies that can emit light of different colors, or light-emitting diode dies that emit light of the same color.

In addition, as shown in FIG. 1, in accordance with some embodiments, the light-emitting element 100 may include a plurality of contact pads 106, and the contact pads 106 may be disposed on the first substrate 202 and contact the first substrate 202. In accordance with some embodiments, the contact pad 106 may be electrically connected to the anode electrode or the cathode electrode of the die of the light-emitting element 100. Specifically, in this embodiment, the light-emitting element 100 has three light-emitting subunits 104a, 104b, and 104c. Three of the contact pads 106 can be electrically connected to the anode electrodes of the dies of the three light-emitting subunits 104a, 104b, and 104c, and one of the contact pads 106 can be electrically connected to the cathode electrode of the dies of the light-emitting subunits 104a, 104b, and 104c. That is, the three light-emitting subunits 104a, 104b, and 104c may have a common cathode. However, the connection manner of the anode electrode or the cathode electrode of the die of the light-emitting element 100 is not limited thereto.

In accordance with some embodiments, the contact pads 106 may include a conductive material. In accordance with some embodiments, the contact pads 106 may include a metal conductive material, a transparent conductive material, or a combination thereof. For example, the metal conductive material may include copper (Cu), aluminum (Al), molybdenum (Mo), silver (Ag), tin (Sn), tungsten (W), gold (Au), chromium (Cr), nickel (Ni), platinum (Pt), copper alloy, aluminum alloy, molybdenum alloy, silver alloy, tin alloy, tungsten alloy, gold alloy, chromium alloy, nickel alloy, platinum alloy, other suitable metal materials, or a combination thereof, but it is not limited thereto. The transparent conductive material may include, for example, transparent conductive oxide (TCO). For example, the transparent conductive oxide may include indium tin oxide (ITO), tin oxide (SnO), zinc oxide (ZnO), indium zinc oxide (IZO), indium gallium zinc oxide (IGZO), indium tin zinc oxide (ITZO), antimony tin oxide (ATO), antimony zinc oxide (AZO), other suitable transparent conductive materials, or a combination thereof, but it is not limited thereto.

In addition, in accordance with some embodiments, the protective layer 108 may be disposed on the intermediate substrate 102 and cover the light-emitting unit 104. In accordance with some embodiments, the protective layer 108 may optionally cover the top surface and the side surface of the light-emitting unit 104. In accordance with some embodiments, in the cross-sectional perspective, the protective layer 108 may have a profile, and at least a portion of the profile may be arc-shaped (not illustrated). In accordance with some embodiments, the protective layer 108 may include an organic material, an inorganic material, other suitable packaging materials, or a combination thereof, but it is not limited thereto. In accordance with some embodiments, the inorganic material may include silicon nitride, silicon oxide, silicon oxynitride, aluminum oxide, or other suitable materials, but it is not limited thereto. In accordance with some embodiments, the organic material may include epoxy resin, silicone resin, acrylic resin (such as polymethylmetacrylate (PMMA), benzocyclobutene (BCB), polyimide, polyester, polydimethylsiloxane (PDMS), polyfluoroalkoxy (PFA), other suitable materials, or a combination thereof, but it is not limited thereto.

Moreover, in accordance with some embodiments, the protective layer 108 may have a wavelength conversion function. For example, the light source generated by the light-emitting units 104 may be converted into light having a specific wavelength range (specific color). In accordance with some embodiments, the protective layer 108 may further include particles with wavelength conversion function, such as phosphors, quantum dot (QD) materials, organic fluorescent materials, other suitable materials, or a combination thereof, but it is not limited thereto.

As shown in FIG. 1, in accordance with some embodiments, the electronic device 10A may further include a reflective layer 204 disposed on the first substrate 202. The reflective layer 204 can improve the light extraction efficiency of the light-emitting elements 100 or increase the amount of emission light. In accordance with some embodiments, the reflective layer 204 may be in contact with the light-emitting elements 100. In accordance with some other embodiments, the reflective layer 204 may not be in contact with the light-emitting elements 100. In accordance with some embodiments, the contact pads 106 of the light-emitting element 100 may be partially embedded in the reflective layer 204. In accordance with some embodiments, the reflective layer 204 may include a material with high reflectivity (for example, the reflectivity may be between 70% and 99%). In accordance with some embodiments, the material with high reflectivity may include silver (Ag), aluminum (Al), titanium (Ti), titanium dioxide (TiO₂), other suitable reflective materials, or a combination thereof, but it is not limited thereto. In accordance with some embodiments, the reflective layer 204 may include white ink, white tape, or white photoresist etc., but it is not limited thereto.

In view of the foregoing, the thin-film transistor array 300 may be disposed on the second substrate 302. In accordance with some embodiments, the thin-film transistor array 300 may be disposed on the side of the second substrate 302 that is farther from the first substrate 202. Furthermore, the thin-film transistor array 300 may include a driving element (not shown). In accordance with some embodiments, the driving element may include thin-film transistors (TFT), but it is not limited thereto. The aforementioned thin-film transistor may include, for example, a switching transistor, a driving transistor, a reset transistor, or other thin-film transistors.

Furthermore, the second substrate 302 may include a rigid substrate or a flexible substrate. In accordance with some embodiments, the material of the second substrate 302 may include glass, quartz, sapphire, polyimide (PI), polycarbonate (PC), polyethylene terephthalate (PET), other suitable materials or a combination thereof, but it is not limited thereto. In addition, in accordance with some embodiments, the material of the second substrate 302 may be different from the material of the first substrate 202.

Moreover, in accordance with some embodiments, the material of the second substrate 302 may include semiconductor materials, such as silicon (Si), germanium (Ge), other suitable semiconductor materials, or a combination thereof, but it is not limited thereto. In accordance with some embodiments, the material of the second substrate 302 may include a silicon wafer. In particular, in the embodiment where the material of the second substrate 302 includes a semiconductor material, a semiconductor process can be used to form the thin-film transistor array 300, which can further improve the performance of the thin-film transistor array 300 and reduce the volume of the thin-film transistor array 300.

In accordance with some embodiments, an area of the second substrate 302 is smaller than an area of the first substrate 202. In accordance with some embodiments, the area of the first substrate 202 refers to the area of the surface of the first substrate 202 provided with the light-emitting elements 100, e.g., the first surface 202a shown in the figure. Furthermore, the area of the second substrate 302 refers to the area of the surface of the second substrate 302 provided with the thin-film transistor array 300, e.g., the first surface 302a shown in the figure.

It should be noted that, the material of the substrate (second substrate 302) provided with the thin-film transistor array 300 is generally expensive. Therefore, when the area of the second substrate 302 provided with the thin-film transistor array 300 is smaller than of the area of the first substrate 202 provided with the light-emitting elements 100, the material amount of the second substrate 302 can be reduced, thereby reducing the production cost.

Furthermore, referring to FIG. 1, in accordance with some embodiments, the thin-film transistor array 300 may further include contact pads 304, and the contact pads 304 may be electrically connected to a driving element (not illustrated). The contact pads 304 may include conductive materials, and the materials of the contact pads 304 may be the same as or similar to the material of the contact pad 106 of the aforementioned light-emitting element 100, and thus will not be repeated herein.

In accordance with some embodiments, the electronic device 10A may further include a conductive film 306, and the conductive film 306 may be in contact with the contact pad 304 and the first substrate 202. Specifically, in accordance with some embodiments, the conductive film 306 may be in contact with a via 210 disposed in the first substrate 202 and the contact pads 304, and the contact pads 304 of the thin-film transistor array 300 may be electrically connected to the contact pad 106 of the light-emitting element 100 through the conductive film 306 and the via 210. Therefore, the electronic signal of the thin-film transistor array 300 can be transmitted to the light-emitting element 100.

In accordance with some embodiments, the conductive film 306 may be flexible and may connect the contact pads 304 and the via 210 in a bent form. In accordance with some embodiments, the conductive film 306 may include a base layer (not illustrated) and a conductive layer (not illustrated) formed on the base layer. In accordance with some embodiments, the material of the base layer may include polyimide (PI), or other suitable flexible materials, but it is not limited thereto. In accordance with some embodiments, the conductive film 306 may be a flexible printed circuit (FPC) board, but it is not limited thereto.

In accordance with some embodiments, the via 210 may penetrate the first substrate 202 and directly contact the contact pad 106 and the conductive film 306. However, in accordance with some embodiments, the via 210 may not directly penetrate the first substrate 202. Instead, the via 210 may contact the contact pad 106 and the conductive film 306 by an interconnection structure (e.g., including a plurality of vias and a plurality of metal layers) to provide electrical connection. Furthermore, in accordance with some embodiments, a through-hole may be formed in the first substrate 202 by one or more photolithography processes, etching processes, laser processes, and/or mechanical processes, and then the through-holes are filled with the conductive material to form the via 210. In accordance with some embodiments, the photolithography process may include photoresist coating (such as spin coating), soft baking, hard baking, mask alignment, exposure, post-exposure baking, photoresist development, cleaning and drying, etc., but it is not limited thereto. The etching process may include a dry etching process or a wet etching process, but it is not limited thereto.

In addition, as shown in FIG. 1, in accordance with some embodiments, the electronic device 10A may further include an electronic component 400 disposed on the first substrate 202. In accordance with some embodiments, the electronic component 400 may be disposed on the second surface 202b of the first substrate 202. That is, the electronic component 400 and the thin-film transistor array 300 may be disposed on the same side of the first substrate 202, but the present disclosure is not limited thereto. In accordance with some embodiments, the electronic component 400 may include driving components such as integrated circuits (IC) or microchips, resistance components, capacitance components, gate on panel (GOP) structures, or other suitable electronic components that can provide electronic signals or logic signals, but they are not limited thereto.

As described above, in accordance with some embodiments of the present disclosure, the light-emitting elements 100 and the thin-film transistor array 300 are disposed on different substrates. It should be noted that, in such a configuration, the selection of the substrate material and manufacturing process of the thin-film transistor array 300 and the light-emitting elements 100 can be independent from each other, thereby improving the process yield or product reliability. Specifically, the light-emitting elements 100 can be disposed on a substrate material that has a better bonding effect or is more conducive to the formation of the via 210, such as ceramic, aluminum, copper, glass fiber, and so on. The substrate material on which the light-emitting elements 100 are disposed can be not limited to those required in the process of forming thin-film transistor array 300, such as glass, quartz, sapphire, polyimide, polycarbonate, polyethylene terephthalate and so on.

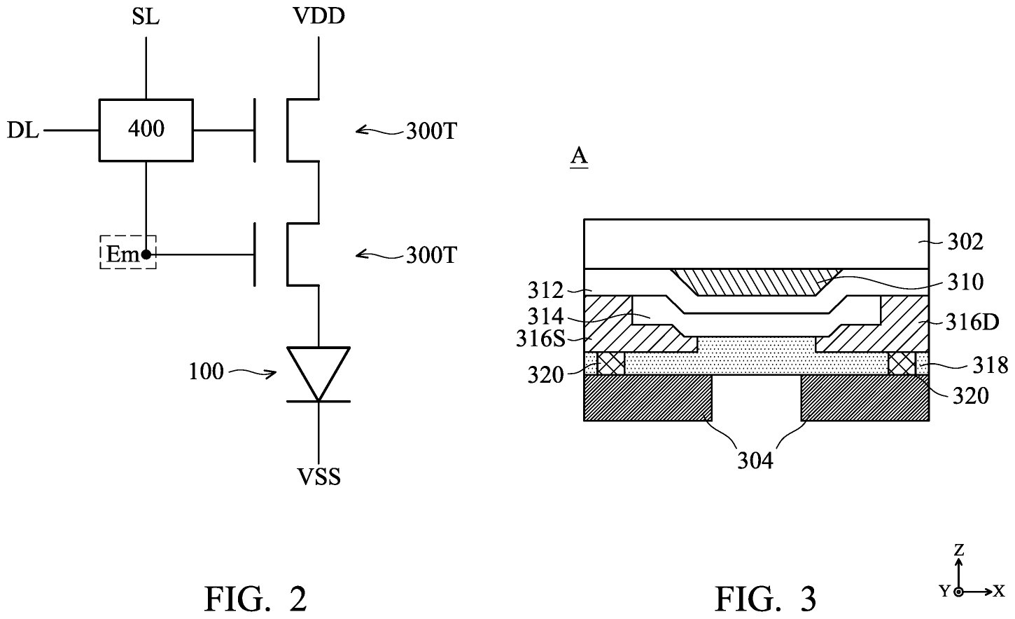

Next, refer to FIG. 2, which is a unit circuit diagram of the electronic device 10A in accordance with some embodiments of the present disclosure. Specifically, FIG. 2 only schematically illustrates the circuit connection relationship of two driving elements (the two thin-film transistors 300T shown in the figure) in the thin-film transistor array 300, one electronic component 400 and one light-emitting element 100 in accordance with some embodiments of the present disclosure.

As shown in FIG. 2, in accordance with some embodiments, a scan line SL and a data line DL can be electrically connected to the electronic component 400. The scan line SL and the data line DL can transmit signals to the electronic component 400, and then the signals can be transmitted to the thin-film transistors 300T, and the thin-film transistors 300T are electrically connected to voltage terminal VDD and voltage terminal VSS. In accordance with some embodiments, the thin-film transistor 300T may include at least one driving transistor and a light-emitting transistor electrically connected to a light-emitting signal terminal Em. The driving transistor and the light-emitting transistor can jointly control whether the light-emitting element 100 emits light or can adjust luminance, etc. The electronic component 400 may include one or more thin-film transistors or/and one or more capacitors, but it is not limited to this. In addition, the electronic component 400 may also have the function of bias compensation and/or storing charges in addition to transmitting the signals of the scan line SL and the data line DL. It should be understood that the thin-film transistor may include a gate, a source, and a drain. When one element is electrically connected to the gate of the thin-film transistor, and another element is electrically connected to the source and/or drain of the thin-film transistor, then the two elements are regarded as being electrically connected with each other. For example, when the data line DL is electrically connected to the gate of the thin-film transistor 300T, and the voltage terminal VDD is electrically connected to the source of the thin-film transistor 300T, then the data line DL is regarded as being electrically connected to the voltage terminal VDD. It should be understood that the configuration relationship of the driving transistors and the light-emitting transistor connected to the light-emitting signal terminal Em is not limited to that shown in the figure. In accordance with various embodiments, a suitable circuit configuration relationship can be adjusted according to needs.

Next, refer to FIG. 3, which is a structural enlarged diagram of region A in FIG. 1 in accordance with some embodiments of the present disclosure. FIG. 3 illustrates the detailed structure diagram of the thin-film transistor array 300 disposed on the second substrate 302. As shown in FIG. 3, in accordance with some embodiments, the thin-film transistor array 300 may include a thin-film transistor structure. Specifically, the thin-film transistor structure may include a gate 310, a gate dielectric layer 312, a semiconductor 314, a source 316S, and a drain 316D, a planarization layer 318, a via 320 and the contact pad 304. In accordance with some embodiments, the gate dielectric layer 312 may be disposed between the semiconductor 314 and the gate 310. In a normal direction of the second substrate 302 (e.g., the Z direction shown in the figure), the semiconductor 314 and the gate 310 may be at least partially overlapped with each other, and the source 316S and the drain 316D are disposed on both sides of the semiconductor 314. In addition, the source 316S and the drain 316D respectively overlap with portions on both sides of the semiconductor 314 in the normal direction of the second substrate 302. Furthermore, in accordance with some embodiments, the planarization layer 318 may cover the source 316S, the drain 316D, and the semiconductor 314, and the via 320 may penetrate a portion of the planarization layer 318 to be electrically connected to the contact pads 304.

In accordance with some embodiments, the material of the gate 310 may include amorphous silicon, polycrystalline silicon, one or more metals, metal nitrides, conductive metal oxide, or a combination thereof, but it is not limited thereto. The metal may include molybdenum, tungsten, titanium, tantalum, platinum, hafnium, or a combination thereof, but it is not limited thereto. The metal nitride may include molybdenum nitride, tungsten nitride, titanium nitride, tantalum nitride, or a combination thereof, but it is not limited thereto.

In accordance with some embodiments, the material of the gate dielectric layer 312 may include silicon oxide, silicon nitride, silicon oxynitride, high-k dielectric materials, other suitable dielectric materials, or a combination thereof, but it is not limited thereto. The high-k dielectric materials may include metal oxides, metal nitrides, metal silicides, transition metal oxides, transition metal nitrides, transition metal silicides, metal oxynitrides, metal aluminate, zirconium silicate, zirconium aluminate, or a combination thereof, but it is not limited thereto.

In accordance with some embodiments, the material of the semiconductor 314 may include amorphous silicon, such as low-temp polysilicon (LTPS), metal oxides, other suitable materials, or a combination thereof, but it is not limited thereto. For example, the metal oxide may include indium gallium zinc oxide (IGZO), indium zinc oxide (IZO), indium gallium zinc tin oxide (IGZTO), other suitable materials, or a combination thereof, but it is not limited thereto. In accordance with some embodiments, different thin-film transistors may include the same semiconductor material or different semiconductor materials, but it is not limited thereto.

In accordance with some embodiments, the materials of the source 316S and the drain 316D may include copper, aluminum, molybdenum, tungsten, gold, chromium, nickel, platinum, titanium, iridium, rhodium, copper alloy, aluminum alloy, molybdenum alloy, tungsten alloy, gold alloy, chromium alloy, nickel alloy, platinum alloy, titanium alloy, iridium alloy, rhodium alloy, other suitable conductive materials, or a combination thereof, but it is not limited thereto.

Furthermore, in accordance with some embodiments, the planarization layer 318 may include organic materials, inorganic materials, other suitable materials, or a combination thereof, but it is not limited thereto. For example, the inorganic material may include silicon nitride, silicon oxide, silicon oxynitride, aluminum oxide, other suitable materials, or a combination thereof, but it is not limited thereto. For example, the organic material may include epoxy resins, silicone resins, acrylic resins (such as polymethylmetacrylate (PMMA)), polyimide, perfluoroalkoxy alkane (PFA), other suitable materials or a combination thereof, but it is not limited thereto.

In accordance with some embodiments, the via 320 may include a conductive material, such as a metal conductive material. In accordance with some embodiments, the metal conductive material may include, aluminum, molybdenum, silver, tin, tungsten, gold, chromium, nickel, platinum, copper alloy, aluminum alloy, molybdenum alloy, silver alloy, tin alloy, tungsten alloy, gold alloy, chromium alloy, nickel alloy, platinum alloy, other suitable metal materials, or a combination thereof, but it is not limited thereto.

In addition, in accordance with some embodiments, the driving element may include a bottom gate thin-film transistor. In accordance with some other embodiments, the driving element may include a top gate thin-film transistor. The driving element can be designed or combined according to needs, but it is not limited thereto.

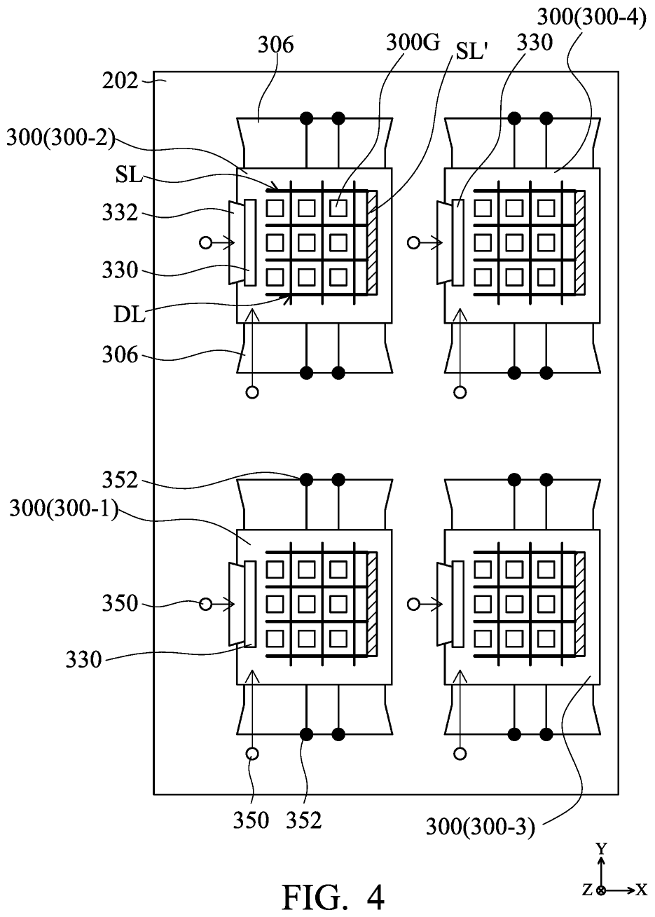

Next, refer to FIG. 4, which is a bottom-view diagram of the electronic device 10A in accordance with some embodiments of the present disclosure. specifically, FIG. 4 illustrates the configuration relationship of the thin-film transistor array 300 and related circuits disposed on the second surface 202b of the first substrate 202. It should be understood that, for clarity of description, FIG. 4 does not illustrates all the circuits disposed on the second surface 202b.

As shown in FIG. 4, in accordance with some embodiments, a plurality of thin-film transistor arrays 300 may be disposed on the second surface 202b. One thin-film transistor array 300 may include a plurality of circuit groups 300G, and the circuit group 300G may include a plurality of thin-film transistors 300T, and the scan lines SL and the data lines DL may intersect with each other to defined the circuit group 300G. The scan lines SL may be electrically connected to a driving integrated circuit (IC) 330, and the scan lines SL may be integrated at one end to form the collected scan line SL.

In accordance with some embodiments, the driving integrated circuit 330 may be disposed on the first substrate 202 and/or the second substrate 302 in the form of chip-on-film (COF) or chip-on-glass (COG). In accordance with some embodiments, the driving integrated circuit 330 may be electrically connected to a connection layer 332, and a signal input terminal 350 can transmit the signal to the driving integrated circuit 330 through the connection layer 332, and then transmit the signal to the circuit group 300G. In addition, the circuit group 300G can transmit the signal to a signal output terminal 352, and then transmit the signal to the light-emitting element 100 disposed on the first substrate 202, and the signal output terminal 352 may be disposed on the conductive film 306.

In accordance with some embodiments, the length of the second substrate 302 may be between about 0.5 millimeters (mm) to about 20 millimeters (mm), or between about 1 millimeter (mm) to about 10 millimeters (mm), for example, 2 millimeters (mm), or 3 millimeters (mm). The width of the second substrate 302 may be between about 0.5 millimeters (mm) to about 20 millimeters (mm), or between about 1 millimeter (mm) to about 10 millimeters (mm), for example, 2 millimeters (mm), or 3 millimeters (mm). In accordance with some embodiments, the length of the second substrate 302 may be the same as the width. That is, the area (length multiplied by width; length*width) of the second substrate 302 may be between about 0.5 mm*0.5 mm to about 20 mm*20 mm (0.5 mm*0.5 mm≤the area of the second substrate 302≤20 mm*20 mm), or between about 1 mm*1 mm to about 10 mm*10 mm, for example, 2 mm*2 mm, or 3 mm*3 mm. In accordance with some other embodiments, the length of the second substrate 302 may be different from the width. The design of the shape and size of the second substrate 302 can be adjusted according to needs, and it is not limited thereto.

Furthermore, in accordance with the embodiments of the present disclosure, an optical microscope (OM), a scanning electron microscope (SEM), a film thickness profiler (α-step), an ellipsometer or another suitable method may be used to measure the area, width, length, thickness of each element or the distance between elements. Specifically, in accordance with some embodiments, a scanning electron microscope can be used to obtain any cross-sectional image including the elements to be measured, and the area, width, length, thickness or distance between the elements in the image can be measured.

In addition, as shown in FIG. 4, in accordance with some embodiments, the thin-film transistor array 300 may be electrically connected to different driving integrated circuits 330, respectively. In other words, in accordance with some embodiments, the driving integrated circuits 330 may drive different thin-film transistor arrays 300. For example, the thin-film transistor array 300-1 and the thin-film transistor array 300-2 shown in the figure are controlled by different driving integrated circuits 330.

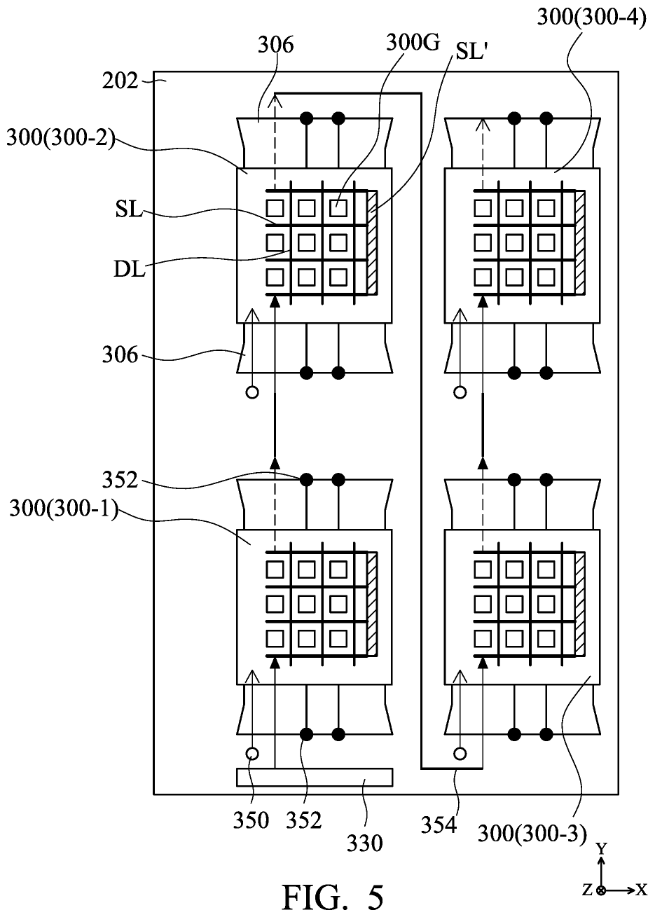

Refer to FIG. 5, which is a bottom-view diagram of the electronic device 10A in accordance with some other embodiments of the present disclosure. As shown in FIG. 5, in accordance with some embodiments, one driving integrated circuit 330 may be electrically connected to a plurality of thin-film transistor arrays 300, and the driving integrated circuit 330 may be disposed on the first substrate 202. In other words, in accordance with some embodiments, a plurality of thin-film transistor arrays 300 may be electrically connected to each other. For example, the thin-film transistor array 300-1 shown in the figure can be electrically connected to the thin-film transistor array 300-2, and several thin-film transistor arrays 300 may be controlled by the same driving integrated circuit 330. In detail, in accordance with some embodiments, the driving integrated circuit 330 may sequentially transmit signals to the thin-film transistor array 300-1, the thin-film transistor array 300-2, the thin-film transistor array 300-3, and the thin-film transistor array 300-4. In addition, in accordance with some embodiments, a conductive circuit 354 may be disposed on the first substrate 202 to connect the thin-film transistor array 300-1, the thin-film transistor array 300-2, the thin-film transistor array 300-3, and the thin-film transistor array 300-4 to make them electrically connected to each other.

Furthermore, in accordance with some other embodiments (not illustrated), the chip-on-film (COF) package may include the driving integrated circuit 330, and the chip-on-film (COF) package may be disposed on the second substrate 302, and electrically connected to the thin-film transistor arrays 300. In addition, the thin-film transistor arrays 300 may be electrically connected to each other, and the thin-film transistor arrays 300 may be controlled sequentially by the driving integrated circuit 330. In such a configuration, one driving integrated circuit 330 can drive several thin-film transistor arrays 300 (that is, several light-emitting elements 100), which can effectively reduce production costs.

Moreover, in addition to the foregoing examples in which the thin-film transistor array 300 is controlled by an active matrix driving circuit, the thin-film transistor array 300 can be controlled by a passive matrix driving circuit in accordance with some other embodiments. Specifically, in accordance with some embodiments, the thin-film transistor 300T in the thin-film transistor array 300 can only be used as a switching transistor to control the switching of the light-emitting element 100, and the electronic device may further include a pulse-width modulation integrated circuit (PWM IC) disposed on the first substrate 202. The pulse-width modulation integrated circuit (PWM IC) can control all signals (currents) driving the light-emitting element 100, generate a PWM signal, and control the luminance of the light-emitting element 100.

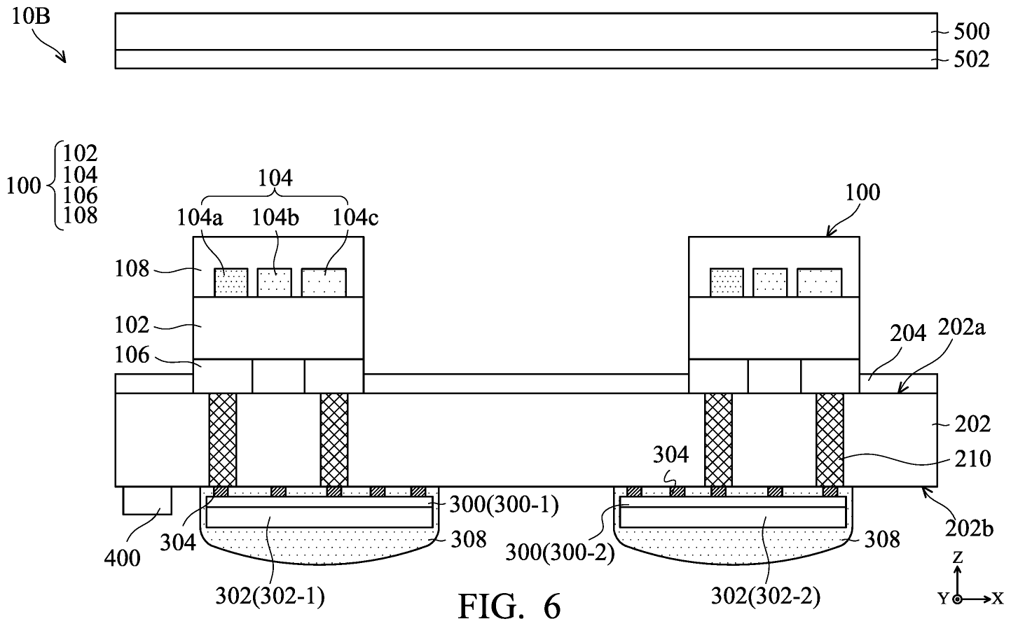

Next, refer to FIG. 6, which is a partial cross-sectional diagram of an electronic device 10B in accordance with some other embodiments of the present disclosure. It should be understood that the same or similar components or elements in the following context will be denoted by the same or similar reference numbers, and their materials, manufacturing methods and functions are the same or similar to those described above, and thus they will not be repeated in the following context.

As shown in FIG. 6, in accordance with some embodiments, the thin-film transistor arrays 300 and the second substrate 302 are also disposed on the second surface 202b of the first substrate 202. The thin-film transistor arrays 300 may be electrically connected to the light-emitting elements 100 on the first surface 202a through the contact pads 304 disposed between the thin-film transistor arrays 300 and the vias 210. In this embodiment, in the same cross-section perspective, the number of the contact pads 304 is more than the corresponding via holes 210 or circuits. It should be understood that each contact pad 304 may have its corresponding circuit and is electrically connected to the conductive wire or conductive layer of the corresponding circuit, but it cannot be fully presented in the perspective shown in the figure. For example, the via 210 or the conductive wire may extend in the first substrate 202 in the Y direction and then in the Z direction. Therefore, the positions of the signal input site and signal output site and the via hole 210 are not limited to the same cross section.

In addition, as shown in FIG. 6, in accordance with some embodiments, the thin-film transistor array 300-1 and the thin-film transistor array 300-2 may be respectively disposed on the different second substrates 302-1 and 302-2, and the thin-film transistor array 300-1 and the thin-film transistor array 300-2 may be used to drive different portions of the light-emitting elements 100. Furthermore, in accordance with some embodiments, a total area of the second substrate 302-1 and the second substrate 302-2 combined is smaller than the area of the first substrate 202. The area of the first substrate 202 and the area of each of the second substrates 302-1 and 302-2 are defined above, and in the interest of brevity they will not be repeated.

In accordance with some embodiments, the electronic device 10B may also include a protective layer 308, and the protective layer 308 may cover the thin-film transistor array 300 and the second substrate 302. In accordance with some embodiments, the protective layer 308 may also be disposed between the first substrate 202 and the thin-film transistor array 300 and between the contact pads 304. In accordance with some embodiments, the protective layer 308 can reduce the risk of moisture in the environment affecting the thin-film transistor arrays 300 or the contact pads 304 and causing corrosion.

In accordance with some embodiments, the protective layer 308 may include organic materials, inorganic materials, other suitable packaging materials, or a combination thereof, but it is not limited thereto. In accordance with some embodiments, the inorganic material may include silicon nitride, silicon oxide, silicon oxynitride, aluminum oxide, or other suitable materials, but it is not limited thereto. In accordance with some embodiments, the organic material may include epoxy resin, silicone resin, acrylic resin (such as polymethylmetacrylate (PMMA)), benzocyclobutene (BCB), polyimide, polyester, polydimethylsiloxane (PDMS), polyfluoroalkoxy (PFA), other suitable materials, or a combination thereof, but it is not limited thereto.

Furthermore, in accordance with some embodiments, the electronic device 10B may be used as a backlight module, and the electronic device 10B may further include a panel 500 and an optical film layer 502 disposed above the light-emitting elements 100. In accordance with some embodiments, the panel 500 may include an upper substrate, a lower substrate, and a display medium layer (not illustrated). The display medium layer may include liquid-crystal. The liquid-crystal may include twisted nematic (TN) liquid-crystal, super twisted nematic (STN) liquid-crystal, vertical alignment (VA) liquid-crystal, in-plane switching (IPS) liquid-crystal, cholesteric liquid-crystal, fringe field switching (FFS) liquid-crystal, other suitable liquid-crystal materials, or a combination thereof, but it is not limited thereto. In accordance with some embodiments, the optical film layer 502 may include a diffuser film, a brightness enhancement film, a prism sheet, a dual brightness enhancement film (DBEF), other suitable functional optical films, or a combination thereof, but it is not limited thereto.

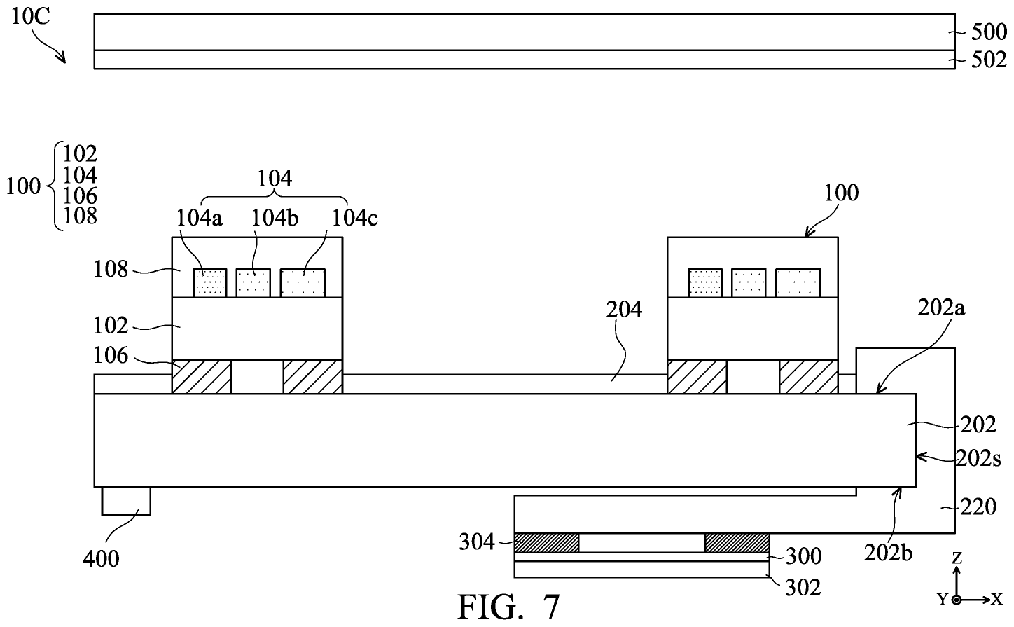

Next, refer to FIG. 7, which is a partial cross-sectional diagram of an electronic device 10C in accordance with some other embodiments of the present disclosure. As shown in FIG. 7, in accordance with some embodiments, the thin-film transistor array 300 and the second substrate 302 are also disposed on the second surface 202b of the first substrate 202. The thin-film transistor array 300 may be electrically connected to the light-emitting element 100 on the first surface 202a through a conductive film 220 disposed on a side surface 202s of the first substrate 202, without additional via structure.

Specifically, in accordance with some embodiments, the conductive film 220 may extend on the second surface 202b, the side surface 202s, and the first surface 202a of the first substrate 202. In accordance with some embodiments, a portion of the conductive film 220 may be disposed between the contact pads 304 and the first substrate 202. Furthermore, in accordance with some embodiments, the conductive film 220 extending on the first surface 202a may be electrically connected to the contact pads 106 of the light-emitting element 100 through a conductive circuit (not illustrated) disposed on the first surface 202a.

In accordance with some embodiments, the conductive film 220 may have flexibility. In accordance with some embodiments, the conductive film 220 may include a base layer (not illustrated) and a conductive layer (not illustrated) formed on the base layer. In accordance with some embodiments, the material of the base layer may include polyimide (PI), or other suitable flexible materials, but it is not limited thereto. In accordance with some embodiments, the conductive film 220 may be a flexible printed circuit (FPC) board or a chip-on-film (COF) package, but it is not limited thereto.

In accordance with some embodiments, the coefficient of thermal expansion (CTE) of the conductive film 220 may be in a range between the coefficient of thermal expansion of the first substrate 202 and the coefficient of thermal expansion of the second substrate 302, or may be substantially the same as the thermal expansion coefficient of the second substrate 302, which can reduce the impact of stress changes caused by thermal expansion and contraction. In accordance with some embodiments, the thermal expansion coefficient of the conductive film 220 may be between the thermal expansion coefficient of glass and the thermal expansion coefficient of polyimide, or may be substantially the same as the thermal expansion coefficient of polyimide.

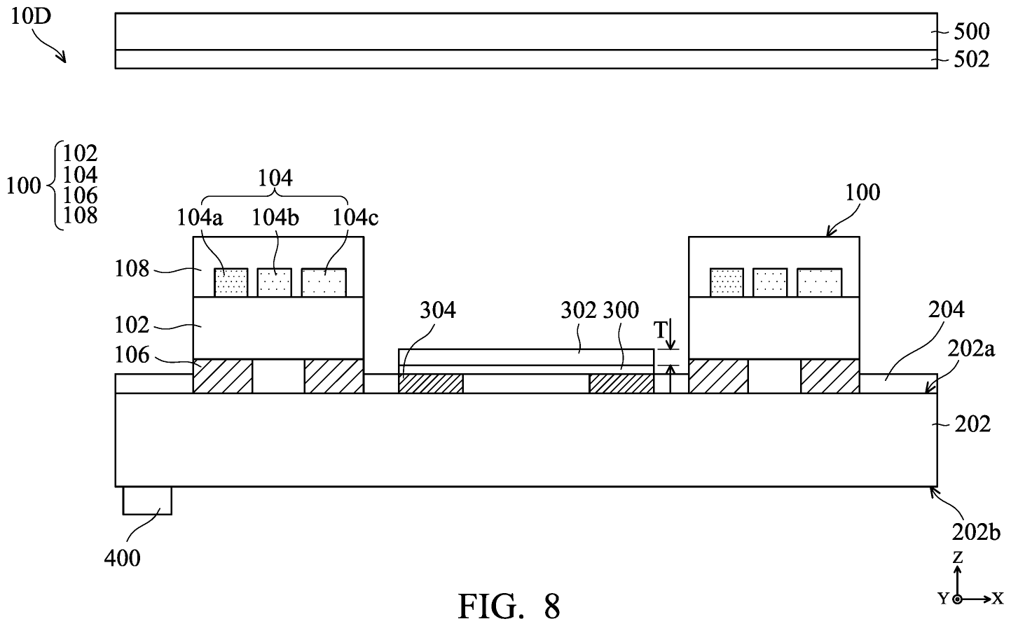

Next, refer to FIG. 8, which is a partial cross-sectional diagram of an electronic device 10D in accordance with some other embodiments of the present disclosure. As shown in FIG. 8, in accordance with some embodiments, the thin-film transistor array 300 and the second substrate 302 are disposed on the first surface 202a of the first substrate 202. That is, the light-emitting elements 100 and the second substrate 302 are disposed on the same side of the substrate 202.

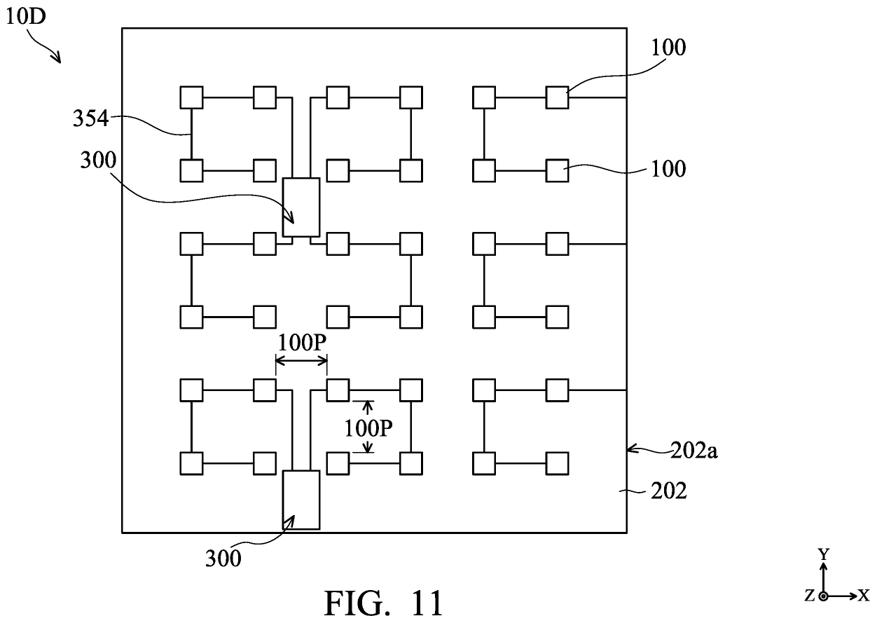

In accordance with some embodiments, the thin-film transistor array 300 and the second substrate 302 may be disposed between the light-emitting elements 100. Specifically, in accordance with some embodiments, the thin-film transistor array 300 and the second substrate 302 may be disposed within a distance 100P between the light-emitting elements 100 (refer to FIG. 11). The thin-film transistor array 300 may be electrically connected to the light-emitting elements 100 through the contact pads 304 and the conductive circuit (not illustrated) disposed on the first surface 202a of the first substrate 202, without additional structures such as vias and conductive films.

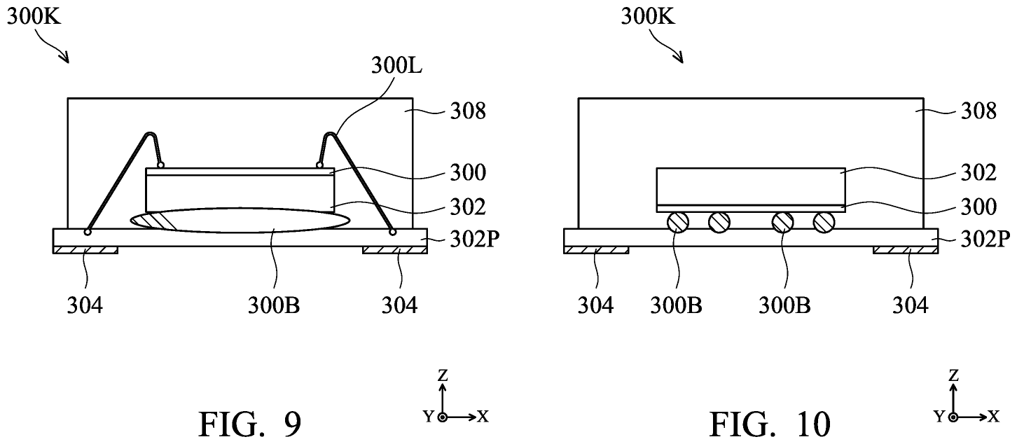

Next, refer to FIG. 9 and FIG. 10. FIG. 9 and FIG. 10 are respectively partial cross-sectional diagrams of the package structures of the thin-film transistor array 300 in accordance with some embodiments of the present disclosure. As shown in FIG. 9 and FIG. 10, in accordance with some embodiments, the thin-film transistor array 300 and the second substrate 302 may be processed by the packaging process first, and may be electrically connected to the light-emitting element 100 in the form of a thin-film transistor array package 300K.

As shown in FIG. 9, in accordance with some embodiments, the thin-film transistor array package 300K may be packaged by wire bonding. In accordance with some embodiments, the thin-film transistor array package 300K may include a packaging substrate 302P, a solder material 300B, and a metal wire 300L. The thin-film transistor array 300 and the second substrate 302 may be fixed to the packaging substrate 302P by the solder material 300B, and the thin-film transistor array 300 may be electrically connected to the packaging substrate 302P and the contact pads 304 through the metal wire 300L.

In accordance with some embodiments, the material of the package substrate 302P may include ceramic, printed circuit board (PCB), flexible printed circuit (FPC) board, leadframe, other suitable package substrates, or a combination thereof, but it is not limited thereto. In accordance with some embodiments, the solder material 300B may include tin, aluminum, tin alloy, aluminum alloy, other suitable solder materials, or a combination thereof, but it is not limited thereto. In accordance with some embodiments, the material of the metal wire 300L may include copper, aluminum, molybdenum, silver, tin, tungsten, gold, chromium, nickel, platinum, copper alloy, aluminum alloy, molybdenum alloy, silver alloy, tin alloy, tungsten alloy, gold alloy, chromium alloy, nickel alloy, platinum alloy, other suitable metal materials, or a combination thereof, but it is not limited thereto. In addition, in accordance with some embodiments, the thin-film transistor array package 300K may further include the protective layer 308. The protective layer 308 may be used as a packaging material to cover the thin-film transistor array 300, the second substrate 302, the solder material 300B and the metal wire 300L.

Furthermore, as shown in FIG. 10, in accordance with some embodiments, the thin-film transistor array package 300K may be packaged in a flip-chip manner. In this embodiment, the solder material 300B may be fixed on the packaging substrate 302P in the form of solder balls, for example, it may be packaged in the form of a ball grid array.

In addition, it should be understood that although the thin-film transistor array package 300K shown in FIG. 9 and FIG. 10 includes the packaging substrate 302P, a conductive film may be used instead of the packaging substrate 302P in accordance with some other embodiments, the present disclosure is not limited thereto.

Next, refer to FIG. 11, which is a top-view diagram of the electronic device 10D in accordance with some embodiments of the present disclosure. Specifically, FIG. 11 illustrates the configuration relationship of the thin-film transistor arrays 300 and the light-emitting elements 100 disposed on the first surface 202a of the first substrate 202. It should be understood that, for clear description, FIG. 11 only illustrates the aforementioned elements, and other elements are omitted.

FIG. 11 is a top-view diagram of FIG. 8. As shown in FIG. 8 and FIG. 11, in accordance with some embodiments, the thin-film transistor arrays 300, the second substrate 302, and the light-emitting elements 100 are all disposed on the first surface 202a of the first substrate 202, and the thin-film transistor arrays 300 and the second substrate 302 may be disposed between the light-emitting elements 100. In accordance with some embodiments, the thin-film transistor array 300 can drive the light-emitting elements 100 connected in series to improve the efficiency of driving the array. In accordance with some embodiments, the thin-film transistor array 300 may be arranged in the distance 100P between two adjacent the light-emitting elements 100. In accordance with some embodiments, in the connection direction of the two light-emitting elements 100 (for example, the X direction or the Y direction shown in the figure), the maximum width of the thin-film transistor array 300 is less than or equal to the distance 100P between two adjacent the light-emitting elements 100. In this embodiment, the bonding processes of the thin-film transistor array 300 and the light-emitting element 100 may be performed on the same surface of the first substrate 202. For example, the thin-film transistor array 300 and the light-emitting element 100 can be fixed on the first surface 202a of the first substrate 202. There is no need to use separate bonding processes to bond the thin-film transistor array 300 and the light-emitting element 100 to the first surface 202a and the second surface 202b of the first substrate 202 respectively, thereby simplifying the manufacturing process.

In accordance with some embodiments, the distance 100P between two adjacent the light-emitting elements 100 extending in the X direction may be the same as the distance 100P between two adjacent the light-emitting elements 100 extending in the Y direction. In accordance with some other embodiments, the distance (not illustrated) between two adjacent the light-emitting elements 100 extending in the X direction may be different from the distance (not illustrated) between two adjacent the light-emitting elements 100 extending in the Y direction.

In addition, in accordance with some embodiments, the conductive circuit 354 may be disposed on the first substrate 202 to connect the thin-film transistor array 300 and the light-emitting elements 100, so that the thin-film transistor array 300 and the light-emitting elements 100 are electrically connected to each other.

In accordance with some embodiments, a thickness T of the second substrate 302 may be less than or equal to 5 millimeters (mm). For example, the thickness T of the second substrate 302 may be less than or equal to 4 millimeters (mm), less than or equal to 3 millimeters (mm), less than or equal to 2 millimeters (mm) or less than or equal to 1 millimeter (mm). In accordance with some embodiments, the second substrate 302 may have a single-layer structure or a multilayer structure. The second substrate 302 may be a multi-layer structure composed of the same material, or may be a multi-layer structure composed of different materials, but it is not limited thereto. For example, the second substrate 302 may have a double-layer structure, the material of the first layer may be glass, and the material of the second layer may be polyimide (PI). The glass may provide a carrier function, which facilitates the placement of circuits or electronic components on polyimide (PI). On the other hand, since the coefficient of thermal expansion (CTE) of the first substrate 202 and the second substrate 302 are different, the second substrate 302 may be cracked. The design of the second substrate 302 with a double-layer structure can reduce the possibility of substrate cracking.

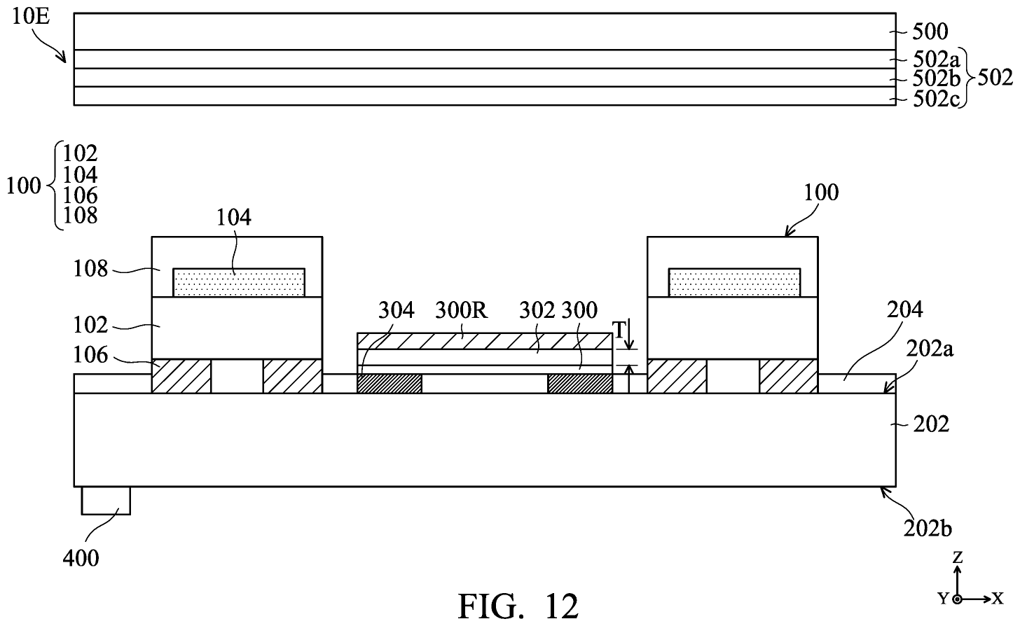

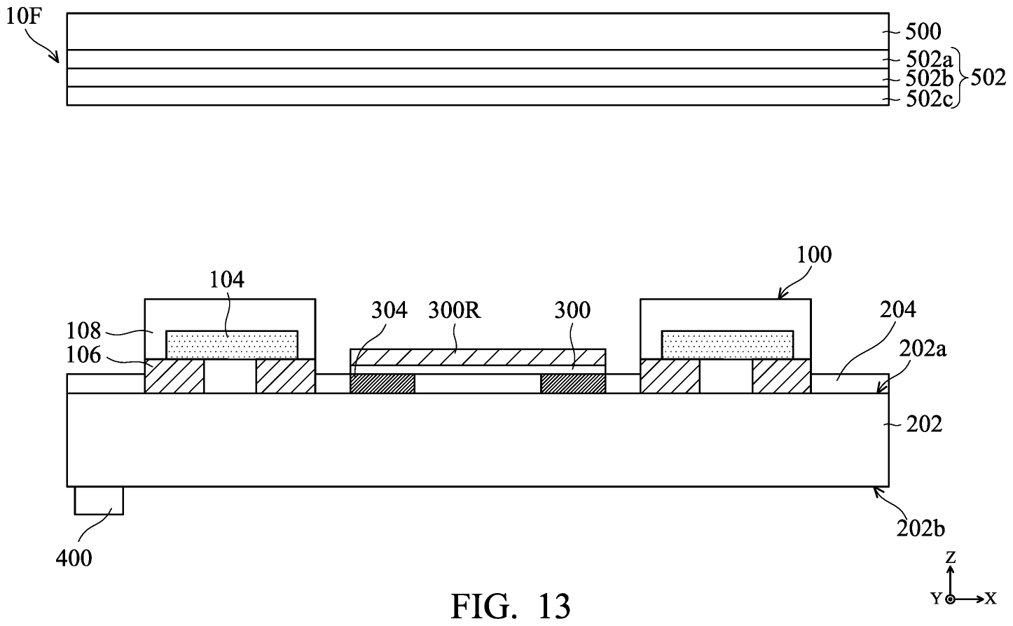

Next, refer to FIG. 12, which is a partial cross-sectional diagram of an electronic device 10E in accordance with some other embodiments of the present disclosure. As shown in FIG. 12, in accordance with some embodiments, the electronic device 10E may further include a reflective layer 300R disposed on the thin-film transistor array 300 and the second substrate 302. The reflective layer 300R can increase the light utilization efficiency of the light-emitting elements 100.

In accordance with some embodiments, the reflective layer 300R may include a material with high reflectivity (for example, the reflectivity may be between 70% and 99%). In accordance with some embodiments, the high-reflectivity material may include silver, aluminum, titanium, titanium dioxide, other suitable reflective materials, or a combination thereof, but it is not limited thereto. In accordance with some embodiments, the reflective layer 300R may include white ink, white tape, or white photoresist, etc., but it is not limited thereto. In accordance with some embodiments, the reflective layer 300R may be directly formed on or attached to the second substrate 302. Furthermore, in accordance with some embodiments, the reflective layer 300R may substantially entirely cover the thin-film transistor array 300, the second substrate 302, and the contact pads 304, thereby reducing the influence of moisture or oxygen in the environment on the thin-film transistor array 300 or contact the pads 304 to cause the risk of corrosion and provide a protective function.

In addition, as shown in FIG. 12, in accordance with some embodiments, the light-emitting element 100 may have a single light-emitting unit 104, and the light-emitting unit 104 may emit light of a single color, such as blue light. In accordance with some embodiments, the optical film layer 502 may further include a sublayer 502a, a sublayer 502b, and a sublayer 502c. In accordance with some embodiments, the sublayer 502a may include a brightness enhancement film, a prism sheet, a reflective brightness enhancement film (DBEF), other suitable functional optical films, or a combination thereof, but it is not limited thereto. In accordance with some embodiments, the sublayer 502b may include a wavelength conversion film, but it is not limited thereto. In accordance with some embodiments, the sublayer 502c may include a diffusion film, but it is not limited thereto. It should be understood that the number and arrangement of the sublayers of the optical film layer 502 are not limited to those shown in the figure. According to different embodiments, a suitable number of sublayers can be adjusted and the sublayers can be arranged in a suitable manner according to needs.

In accordance with some embodiments, the material of the light conversion film layer may include QD, fluorescence, and phosphorescence, but it is not limited thereto. In accordance with some embodiments, the light-emitting unit 104 may emit blue light, and the blue light generated by the light-emitting unit 104 can be converted into light with a specific wavelength range (specific color) through the wavelength conversion film in the optical film layer 502, e.g., red light, green light, yellow light or white light, etc., but the present disclosure is not limited thereto.

Next, refer to FIG. 13, which is a partial cross-sectional diagram of an electronic device 10F in accordance with some other embodiments of the present disclosure. As shown in FIG. 13, in accordance with some embodiments, the light-emitting element 100 may not have the intermediate substrate 102, and the light-emitting unit 104 may directly contact the contact pads 106. In accordance with some embodiments, the thin-film transistor array 300 also may be in direct contact with the contact pads 304 without the second substrate 302 being additionally disposed. In such a configuration, the overall thickness of the electronic device 10F can be reduced or the production cost can be lowered.

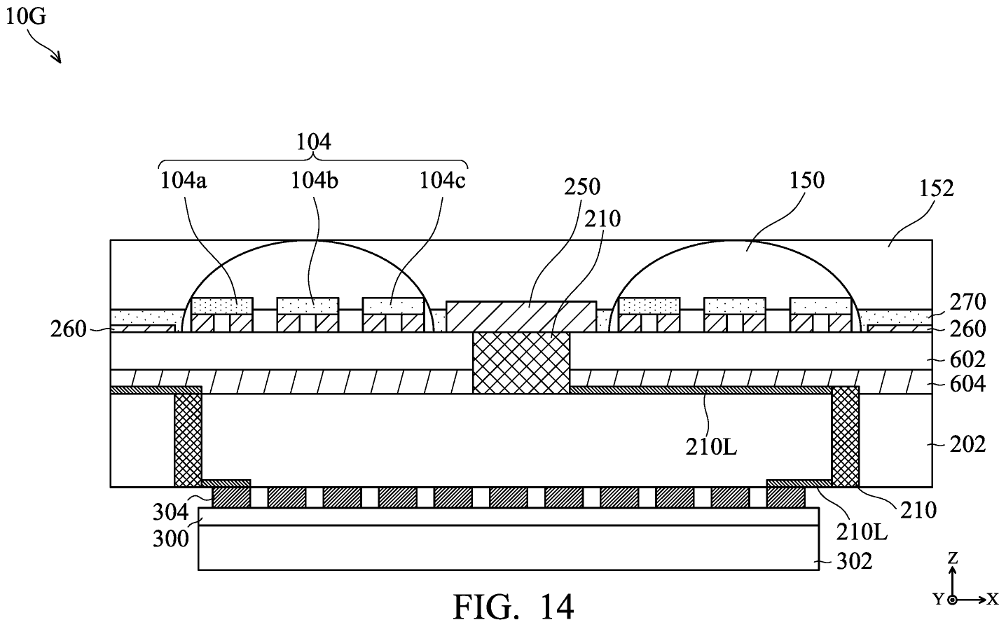

Next, refer to FIG. 14, which is a partial cross-sectional diagram of an electronic device 10G in accordance with some other embodiments of the present disclosure. As shown in FIG. 14, in accordance with some embodiments, the light-emitting unit 104 may include the light-emitting subunit 104a, the light-emitting subunit 104b, and the light-emitting subunit 104c. The light-emitting subunit 104a, the light-emitting subunit 104b, and the light-emitting subunit 104c may be disposed on the same intermediate substrate 602. In addition, the electronic device 10G may further include a jumper pad 250, and the jumper pad 250 may be disposed on the intermediate substrate 602 and between two adjacent light-emitting units 104. The jumper pad 250 may be electrically connected to the via 210 that penetrates the intermediate substrate 602 and an adhesive layer 604, and be electrically connected to the via 210 that penetrates the first substrate 202. In accordance with some embodiments, the signal of the thin-film transistor array 300 can be transmitted to the jumper pad 250 through the vias 210 and an interconnection structure 210L. In accordance with some embodiments, the jumper pad 250 can collect signals and transmit the signals to several light-emitting units 104 that are electrically connected thereto the jumper pad 250.

In accordance with some embodiments, the material of the intermediate substrate 602 may be the same as or similar to the material of the aforementioned intermediate substrate 102, and thus will not be repeated herein. In accordance with some embodiments, the material of the adhesive layer 604 may include any suitable material with adhesiveness. In accordance with some embodiments, the material of the adhesive layer 604 may include a light-curing adhesive material, a heat-curing adhesive material, a light-heat curing adhesive material, other suitable materials, or a combination thereof, but it is not limited thereto. For example, in accordance with some embodiments, the adhesive layer 604 may include optical clear adhesive (OCA), optical clear resin (OCR), pressure sensitive adhesive (PSA), other suitable adhesive materials, or a combination thereof, but it is not limited thereto.

In accordance with some embodiments, the material of the jumper pad 250 may include a metal conductive material, a transparent conductive material, or a combination thereof. For example, the metal conductive material may include copper, aluminum, molybdenum, silver, tin, tungsten, gold, chromium, nickel, platinum, copper alloy, aluminum alloy, molybdenum alloy, silver alloy, tin alloy, tungsten alloy, gold alloy, chromium alloy, nickel alloy, platinum alloy, other suitable metal materials, or a combination thereof, but it is not limited thereto. The transparent conductive material may include a transparent conductive oxide (TCO). For example, the transparent conductive oxide may include indium tin oxide (ITO), tin oxide (SnO), zinc oxide (ZnO), indium zinc oxide (IZO), indium gallium zinc oxide (IGZO), indium tin zinc oxide (ITZO), antimony tin oxide (ATO), antimony zinc oxide (AZO), other suitable transparent conductive materials, or a combination thereof, but it is not limited thereto.

Moreover, in accordance with some embodiments, the conductive material in the via 210 may be filled by an electroplating process or a soldering process. For example, in accordance with some embodiments, the via 210 contacting the jumper pad 250 may be formed by a soldering process (for example, filling solder paste), or the via 210 of the first substrate 202 may be formed by an electroplating process. Alternatively, when the substrate 202 has a multi-layer structure (not illustrated), the via 210 and the circuit may be formed by a photolithography process, an etching process, or an electroplating process. In accordance with some embodiments, a portion of the via 210 may be located in one layer of the first substrate 202, and another portion of the via 210 may be located in another layer of the first substrate 202 (not illustrated), but the present disclosure is not limited thereto.

As shown in FIG. 14, in accordance with some embodiments, the electronic device 10G may further include a test pad 260. The test pad 260 may be used to test whether the electrical connection or brightness of the light-emitting unit 104 is normal. The material of the test pad 260 can be the same as or similar to the material of the jumper pad 250, and thus will not be repeated herein. In accordance with some embodiments, the electronic device 10G may not include the test pad 260.

Furthermore, in accordance with some embodiments, the electronic device 10G may further include a light absorption layer 270, a light extraction layer 150, and a protective layer 152. The light absorption layer 270 may cover the test pads 260, and the light extraction layer 150 may cover the light-emitting units 104, and the light absorption layer 270 may be in contact with portions of the light extraction layer 150 and the jumper pad 250. In accordance with some embodiments, the protective layer 152 may be disposed on the light absorbing layer 270 and the jumper pad 250, and the protective layer 152 may reduce the moisture in the environment from affecting the jumper pad 250 or the light-emitting unit 104, or improve the reliability of the electronic device 10G. In accordance with some embodiments, the top surface of the protective layer 152 may be substantially aligned with the top surface of the light extraction layer 150. In accordance with some other embodiments, the top surface of the protection layer 152 may be higher than the top surface of the light extraction layer 150. In accordance with some embodiments, the protective layer 152 and the light extraction layer 150 may be provided alternatively.

In accordance with some embodiments, the light absorption layer 270 may absorb at least part of the interference light, reduce the influence of the interference light on the image, or improve the contrast or brightness of the light-emitting unit 104. In accordance with some embodiments, the material of the light absorption layer 270 may include a high-absorption material, a low-reflectivity material, or a combination thereof, but it is not limited thereto. In accordance with some embodiments, the material of the light absorption layer 270 may include particles, paint, glue, other suitable materials, or a combination thereof, but it is not limited thereto. In accordance with some embodiments, the light absorption layer 270 may include black organic materials, black inorganic materials, polyethylene terephthalate, black ink, black tape, other suitable materials, or a combination thereof, but it is not limited thereto.

Furthermore, in accordance with some embodiments, the materials of the light extraction layer 150 and the protective layer 152 may be the same as or similar to the material of the protective layer 108, and thus will not be repeated herein. In accordance with some embodiments, the refractive index of the light extraction layer 150 may be between 1 to 2.4 (i.e. 1≤the refractive index of the light extraction layer 150≤2.4), or between 1.2 to 2.2, or between 1.5 to 2.0. In accordance with some embodiments, the refractive index of the protective layer 152 may be between 1 to 2.4 (i.e. 1≤ the refractive index of the protective layer 152≤2.4), or between 1.2 to 2.2, or between 1.5 to 2.0. It should be noted that, in accordance with some embodiments, when the refractive index of the protective layer 152 is between 1 to 2.4, the light extraction efficiency of the light-emitting element 100 can be increased or the total reflection can be reduced. In accordance with some embodiments, the refractive index of the light extraction layer 150 may be substantially the same as the refractive index of the protective layer 152.

To summarize the above, the electronic device provided by the present disclosure includes light-emitting elements and thin-film transistor arrays disposed on different substrates. As a result, the selection of the substrate material and manufacturing process of the thin-film transistor array and the light-emitting element can be independent from each other. Therefore, the process yield, or the product reliability can be improved, or the costs can be reduced. In addition, in accordance with some embodiments, the size of the substrate on which the thin-film transistor array is disposed is smaller than the size of the substrate on which the light-emitting element is disposed, thereby increasing the space available for electrical connection between the thin-film transistor array and the light-emitting element (for example, increasing the connection space or increasing the number of contacts).

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods or steps. In addition, each claim constitutes an individual embodiment, and the claimed scope of the present disclosure includes the combinations of the claims and embodiments. The scope of protection of present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a first substrate;
a plurality of light-emitting elements disposed on the first substrate, comprising:
a contact pad;
an intermediate substrate disposed on the contact pad; and
a light-emitting unit disposed on the intermediate substrate;
a second substrate; and
a first thin-film transistor array disposed on the second substrate for driving at least a portion of the plurality of light-emitting elements,
wherein the light-emitting unit is electrically connected to the contact pad through a via hole that penetrates the intermediate substrate.

2. The electronic device as claimed in claim 1, wherein an area of the second substrate is smaller than an area of the first substrate.

3. The electronic device as claimed in claim 1, wherein the plurality of light-emitting elements comprise a plurality of light-emitting diode packages, a plurality of light-emitting diode chips, or a combination thereof.

4. The electronic device as claimed in claim 1, wherein the plurality of light-emitting elements are arranged in an array.

5. The electronic device as claimed in claim 1, further comprising:
a second thin-film transistor array, wherein the second thin-film transistor array is disposed on a third substrate, and the first thin-film transistor array and the second thin-film transistor array are used to drive different portions of the plurality of light-emitting elements.

6. The electronic device as claimed in claim 5, wherein a total area of the second substrate and the third substrate is smaller than an area of the first substrate.

7. The electronic device as claimed in claim 6, wherein the first thin-film transistor array and the second thin-film transistor array are electrically connected.

8. The electronic device as claimed in claim 1, wherein the plurality of light-emitting elements and the second substrate are disposed on different sides of the first substrate.

9. The electronic device as claimed in claim 1, wherein a material of the second substrate is different from a material of the first substrate.

10. The electronic device as claimed in claim 1, wherein the first thin-film transistor array is electrically connected to the plurality of light-emitting elements through a plurality of contact pads and a via disposed in the first substrate.

11. The electronic device as claimed in claim 1, wherein in a cross sectional view of the electronic device, a maximum width of the first thin-film transistor array is less than or equal to a distance between the at least two of the plurality of light-emitting elements.

12. The electronic device as claimed in claim 1, wherein a material of the second substrate 302 comprises glass or polyimide (PI).
